(19) United States
(12) Patent Application Publication
(10) Pub. No.: US 2026/0196761 A1
(43) Pub. Date: Jul. 9, 2026

(54) SPRING CONTACT PIN

(71) Applicant: Feinmetall GmbH, Herrenberg (DE)

(72) Inventors: Wahid Nassrat, Herrenberg (DE); Marko Martic, Sindelfingen (DE)

(21) Appl. No.: 19/132,750

(22) PCT Filed: Nov. 24, 2022
(86) PCT No.: PCT/EP2022/083206

§ 371 Date: May 23, 2025

(51) Int. Cl. H01R 13/24; G01R 1/067

(52) U.S. Cl. CPC H01R 13/2421; G01R 1/06722

(57) ABSTRACT

The invention relates to a spring contact pin (1) for electrically conductively directly contacting a contact partner, with a sleeve-shaped housing (2) and with a contact element (3), which is supported in the housing (2) in a longitudinally displaceable manner and which has a plunger (6), which lies at least partially in the housing (2), and a contact head (4), which lies outside the housing (2) with a contact surface (5) for directly contacting the contact partner, wherein a spring element (14), in particular coil spring, is arranged in the housing (2) in such a way that the contact element (3) can compressingly engage into the housing (2). It is provided that the plunger (6) is formed in a tubular manner as hollow plunger and that the contact surface (5) of the contact head (4) is formed in a closed manner.

### CROSS REFERENCE TO RELATED APPLICATIONS

This application is a U.S. National Stage Application under 35 U.S.C. 371 of International Application No. PCT/EP 2022/083206, filed Nov. 24, 2022, the contents of which are hereby incorporated by reference in their entirety into the present disclosure.

The present invention relates to a spring contact pin for electrically conductively directly contacting a contact partner, with a sleeve-shaped housing and with a contact element, which is supported in the housing in a longitudinally displaceable manner and which has a plunger, which lies at least partially in the housing, and a contact head, which lies outside the housing with a contact surface for directly contacting the contact partner, wherein a spring element, in particular coil spring, is arranged in the housing in such a way that the contact element can compressingly engage into the housing.

Conventional spring contact pins of this type are used, for example, to check electrical or electronic components, such as, for example, printed circuit boards or the like, for the proper function thereof, wherein the spring contact pins prevent an overstraining of the contact point by means of the compressing engagement into the housing. If several spring contact pins are used, which lie next to one another, all contact points of the opposite contact partner can be contacted securely because the spring contact pins can optimally compensate tolerances by means of the compressing engagement of the respective contact element. Spring contact pins are thus produced and used in large quantities. Spring contact pins are thereby also exposed to a mechanical wear, which is created when the contact element compressingly engages into the housing. Wear in particular occurs due to contact element, in particular plunger, spring element and housing rubbing against each other, when the plunger is inserted into the housing against the force of the spring element. However, a secure and lasting contacting of plunger and housing is advantageous for the electrical conductivity of the spring contact pin. The individual components of the spring contact pin are usually formed in an electrically conductive manner and are optionally provided with electrically conductive coatings, in order to offer an electrical resistance, which is as low as possible. Mechanical and electrical functions or malfunctions mutually influence each other thereby. A wear of the mechanics is also always associated with a damage to the surfaces and the coating or tempering thereof, which may be present, such as, for example, in the form of a noble metallization. Contact means gets lost thereby and the electrical resistance increases. In addition, abrasion particles can attach, which impact the mechanical function as well as the electrical function. To avoid friction corrosions, it is known, for example, to provide protective layers on the contact points or to introduce lubricant, for example.

The present invention is based on the object of creating an improved spring contact pin, which, due to reduced wear, has a higher service life than known spring contact pins, without impacting the electrical conductivity thereby.

The object on which the invention is based is solved by means of a spring contact pin with the features of claim 1. Said contact pin has the advantage that the wear of the spring contact pin is reduced by means of a simple structural measure, without sacrificing the electrical conductivity and thus the functionality of the spring contact pin thereby. Instead, the conductivity is increased due to the formation of the spring contact pin according to the invention.

According to the invention, this is achieved in that the plunger is formed in a tubular manner as hollow plunger and that the contact surface of the contact head is formed in a closed manner. The formation of the plunger as hollow plunger, so that the plunger is formed in a tubular or sleeve-shaped manner, results in a weight savings in the contact element, so that less mass has to be moved in response to the conversion process. The spring element can thus be designed with reduced spring force, wherein the forces acting in the spring contact pin are reduced in response to a contact process. This is associated with the fact that the contact forces and thus the wear in the spring contact pin is also reduced. This thus results in the above-mentioned advantages. Due to the fact that the contact head or the contact surface thereof, respectively, is formed in a closed manner, no disadvantage whatsoever results in response to the direct contacting of the contact partner by means of the tubular formation of the plunger. In the case of a formation of the contact element in a tubular manner as a whole, the contact head would always be provided with an opening, which would result in response to the shaping of the contact element for the formation of the contact head. It is attained by means of the closed formation that the accuracy of the contact element or of the spring contact pin, respectively, is increased significantly, in contrast, and that a secure electrical contact or a secure electrically conductive connection, respectively, is always established.

The contact head is preferably formed as solid element or solid body, thus does not have a hollow space. In addition, the contact head according to the invention has a plug-in section, which is axially inserted into the plunger. The tubular plunger can be produced independently of the contact head due to this two-piece formation of the contact element. This offers advantages, both with regard to the production process and with regard to the variability of the formation of the contact element. A plurality of different contact heads can thus be connected to the same plunger. In particular a spring contact pin system is thus offered, which has a plurality of plungers and contact heads, wherein at least two of the contact heads are formed differently. During the assembly, the person of skill in the art can thus choose between matching contact heads, for example as a function of the contact partner to be contacted, or other boundary conditions.

The plunger is preferably formed as deep-drawn part. Due to the two-piece formation of the contact element, it is possible to also use the technique of deep-drawing, which is known per se, for the plunger. The deep-drawing process is known per se and has proven itself for decades in the case of similarly shaped elements. By means of the deep-drawing process, particularly narrow tolerances can be chosen, which ensure an improved interaction of the contact element, in particular of the plunger, with the housing. Due to the formation as hollow plunger, in particular in the form of a deep-drawn part, the wall of the hollow plunger can additionally be formed in a very thin manner, without risking critical losses of the stability or load capacity of the contact element. The material usage is thus several times lower compared to solid body plungers.

It is furthermore preferably provided that the plug-in section for the electrical and mechanical connection to the plunger is held in/on the plunger in a non-positive manner, in a positive manner and/or by means of a substance-to-substance bond. The plunger and the contact head are thus firmly connected to one another, so that the secure cohesion of the spring contact pin, in particular of the contact element, is also ensured during operation or during a test procedure, respectively. Particularly preferably, the plug-in section is held in/on the plunger by means of pressing, flanging, crimping, welding and/or soldering. This results in a permanently captive connection of plunger and contact head with advantageous electrical conductivity.

According to a preferred further development of the invention, the plunger has a cross sectional tapering between its ends, wherein the spring element extends into the plunger and supports itself axially on the cross sectional tapering on the one hand and on a housing end of the housing facing away from the plunger on the other hand. The spring element is thus axially pretensioned between housing end and plunger, wherein the spring element supports itself on the cross sectional tapering of the plunger for this purpose. The cross sectional tapering does not sit on one of the ends but between the ends of the plunger, so that the spring element protrudes all the way into the plunger, wherein the tubular shape of the plunger readily provides for a reception of the spring element. The arrangement of the spring element partially within the plunger results in the advantage that parts of the spring element are not guided through the housing but only through the plunger. Wear or friction in interaction with the housing is thus also not created on these parts of the spring element. The contact points of the housing, which are otherwise contacted by the plunger even in response to the displacement thereof, are thus protected against an excessive wear.

It is furthermore preferably provided that, viewed in the axial extension, the cross sectional tapering of the plunger is arranged closer to the head than to the end of the plunger facing the housing end. This has the result that a region of the spring element, viewed in its axial extension, is guided within the plunger and thus acts in a wear-reducing manner. The spring force is not impacted thereby.

The spring element preferably has at least one stiff spring element section. An elastic deformation of the spring element in response to a contacting process is avoided in the stiff spring element section. In this respect, the stiff spring element section is understood to be a section of the spring element in its longitudinal extension, in which a compression in the longitudinal extension is not or hardly possible. A deformation transversely to the longitudinal extension is additionally also at least essentially prevented due to the stiff formation, so that the spring element can also not buckle or bend laterally in the stiff spring element section. A region of the spring element, which, on the one hand, does not exert a spring force in response to the test procedure and which, on the other hand, prevents a deformation of the spring element, is thus defined by means of the stiff spring element section. For example, the wear in the region of the transition of the spring element from the housing into the contact plunger can be reduced by means of an advantageous placement of the stiff spring element section.

The stiff spring element section preferably lies at least essentially between the plunger and the housing end. At least in the non-actuated state, the stiff spring element section lies completely between plunger and housing end, viewed in the longitudinal extension of the spring element. The compressing engagement through the spring element section, which in particular remains within the plunger, is made possible and ensured thereby. Due to the fact that the stiff spring element section lies outside the plunger or at least essentially outside the plunger, it is achieved that a deformation of the spring element in such a way that it comes into contact, in particular in frictional contact with the housing or the inner wall thereof, is reduced or prevented there. The larger the spring element section of the spring element within the plunger, the more the wear of the spring contact pin is reduced as a whole. The stiff spring element section thereby preferably has an outer diameter, which is smaller than the inner diameter of the housing, so that a direct contact, in particular a frictional contact, between the stiff spring element section and the housing is avoided. A frictional contact of the spring contact pin is thereby limited in particular to the interaction of housing and plunger.

On its end facing the housing, the plunger preferably has a lead-in chamfer for the spring element. The reception of the spring element in its longitudinal extension into the plunger is thus simplified in response to the compressing engagement. In particular, wear is prevented thereby and the spring element is also in particular prevented from catching or canting on the front side of the plunger facing the housing end. On the contrary, the spring element is centered or guided into the plunger, respectively, by means of the lead-in chamfer.

It is furthermore preferably provided that the housing end of the housing is plastically deformed, in particular bent over, for the formation of an axial stop for the spring element. Due to the advantageous formation of the housing end, a simple assembly of the spring contact pin is made possible. During the assembly, the housing end is in particular not bent over yet, so that the contact element can be inserted or is inserted into the housing from the rear, thus through the housing end. The housing end is plastically deformed only afterwards, in order to offer an axial stop for the spring element and in order to prevent the plunger from falling out of the housing in the direction of the housing end. An assembly improvement, which is furthermore designed in an installation space-saving manner and in a reliable manner, is achieved here with simple cost-efficient means.

According to a preferred further development of the invention, the housing has, on its end facing away from the housing end, a cross sectional tapering, which forms a step, wherein the step is formed as axial stop for the plunger, which acts against the force of the spring element. The plunger is thus held in a longitudinally displaceable manner between the spring element, which supports itself on the housing end on the one hand, and on the axial stop on the other hand. The plunger can thus also not be ejected by means of the spring element on the side of the housing facing away from the housing end by means of the spring element. The spring contact pin is cost-efficient and not very prone to errors due to this structurally simple formation.

The cross sectional tapering of the housing is in particular produced by means of a deep-drawing process. The housing as a whole is in particular produced by means of a deep-drawing process. The housing can thus be produced in large quantities in a simple and precise manner.

According to a preferred further development of the invention, the length of the distance of the plunger, which lies at least in the housing, corresponds to the length of the housing minus the maximally permissible spring deflection of the spring element and minus a specifiable tolerance value. The plunger thus extends almost completely through the housing. Due to the fact that the spring element runs within the plunger, this is not disadvantageous for the spring deflection. Due to the formation of the plunger, which is long compared to the housing, however, an improved storage of the plunger in the housing is ensured, with simultaneously improved electrical connection between housing and plunger. Due to the fact that the spring deflection and a specifiable tolerance value are considered when defining the length of the plunger, it is ensured that the desired minimum or maximum spring deflection is always attained.

The end of the spring element facing the housing is preferably widened. An improved support of the spring element on the housing end is thus offered. As described above, the housing end is in particular deformed subsequently by means of a shaping process for forming an axial stop, whereby an opening remains in the housing end. The wider the spring element is formed at the point, which supports itself on the housing end, the less likely it is that the spring element reaches into the opening and gets caught therein and/or catches. The widening of the spring element thus results in an improved support.

It is furthermore preferably provided that outside the plunger, the spring element has a longitudinal section, along which the outer diameter of the spring element widens in the direction of the housing end, so that the spring element, except for the plunger, abuts on the inner wall of the housing. The spring element is then radially guided within the plunger through the plunger as well as outside the plunger through the housing in this case, whereby a particularly secure guidance of the spring element, which prevents a bending out, is ensured. The wear between spring element and housing thus increases nonetheless.

According to an alternative embodiment of the invention, this longitudinal section is thus particularly preferably formed as the stiff section of the spring element. The stiff spring element section thus lies outside the plunger thereby. Due to the fact that the spring element section is formed in a stiff manner, no relative movement is created between the spring element section or the bonds between the coil spring and the housing, respectively, during a springing process. Instead, the spring is held and centered or guided, respectively, only radially in the housing. The spring function is ensured in particular by means of the section of the spring element, which is located within the plunger. In addition, this results in the advantage that a lateral buckling or bending of the spring element is prevented. The stiff spring element section is preferably formed in that the coils of the coil spring abut axially on one another, whereby a compression in the axial direction is prevented because the applied coils act like a continuous bar.

According to a preferred further development of the invention, the plunger has, on its end facing the housing, a cross sectional tapering, on which the spring element supports itself. In contrast to the cross sectional tapering, which is located between the two ends of the plunger, it is provided according to this embodiment that the spring element does not extend into the plunger. Even though the advantages of the spring contact pin with regard to the reduced weight, the reduced spring force and the reduced wear between plunger and housing remain, a slightly increased wear is created in that the elastically deformable part of the spring element lies outside the plunger. The spring element can nonetheless be produced even more cost-efficiently thereby because, for example, the spring element length can be reduced compared to the preceding embodiment.

According to this embodiment, the cross sectional tapering preferably has a centering chamfer for centering the spring element between the plunger and the housing. The spring element is thus radially centered or caught, respectively, between plunger and housing, so that a secure guidance of the spring element and of the plunger in the housing is ensured. The centering chamfer in particular has an inner diameter, which is smaller than the inner diameter of the spring element, so that the centering chamfer can be partially inserted into the spring element.

It is furthermore preferably provided that the spring element has, on its end facing the plunger, a diameter tapering for centering the spring element to the plunger. According to an alternative embodiment, the spring element thus partially penetrates into the plunger, in order to be centered therein. This results in the advantages with regard to the centering, which have already been mentioned above.

Further advantages and preferred features and feature combination follow in particular from what has been described above as well as from the claims. The invention will be explained in more detail below on the basis of the drawing, for the purpose of which

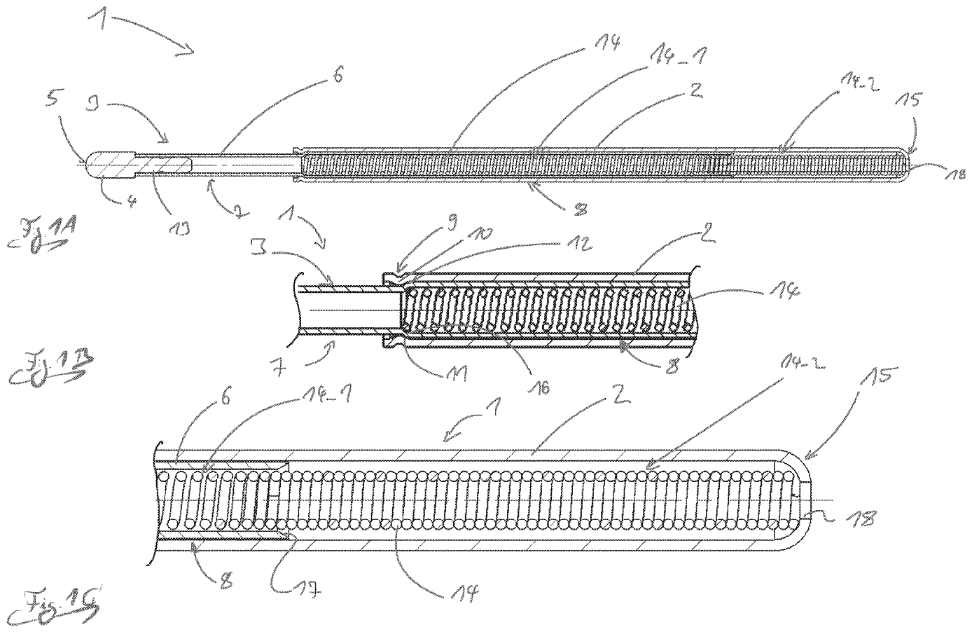

FIG. 1A to E shows a first exemplary embodiment of an advantageous spring contact pin,

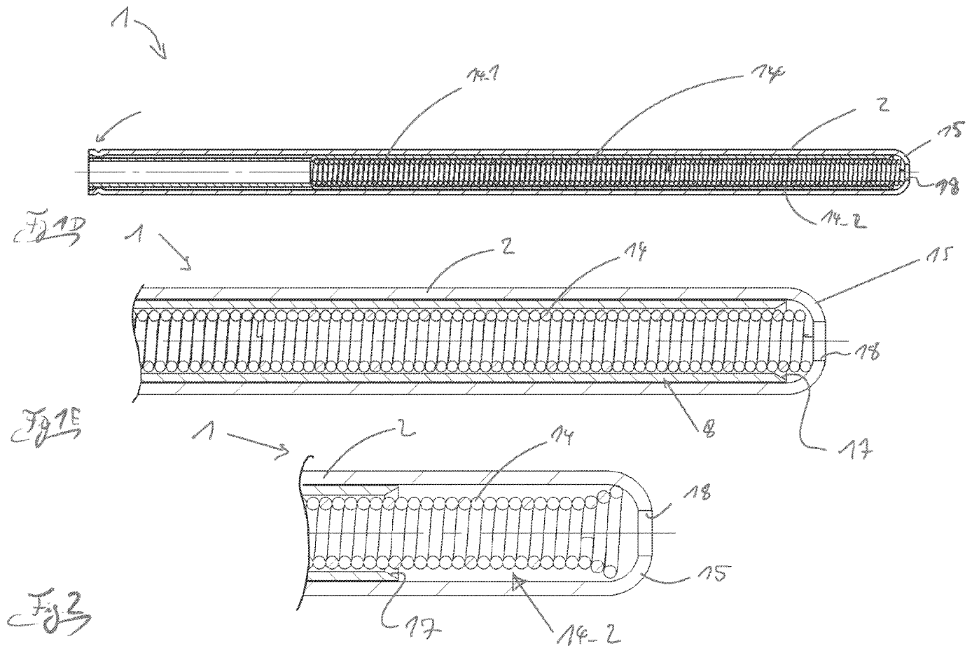

FIG. 2 shows a second exemplary embodiment of the spring contact pin,

FIG. 3A and B show a third exemplary embodiment of the spring contact pin,

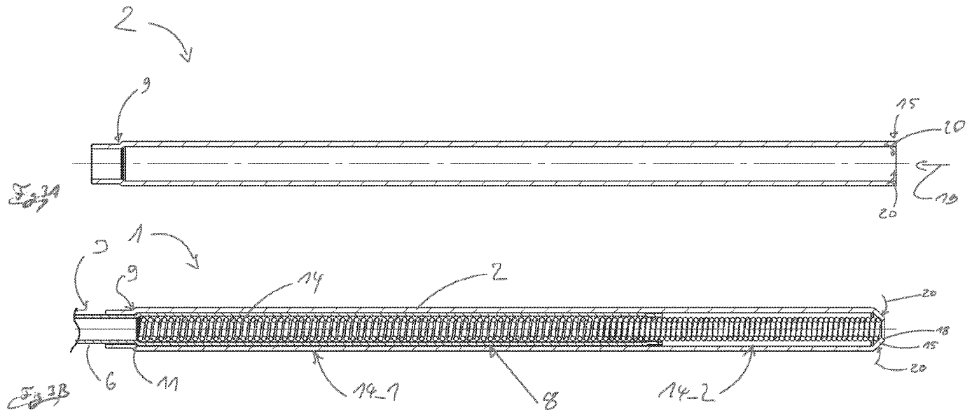

FIG. 4 shows a fourth exemplary embodiment of the spring contact pin,

FIG. 5 shows a fifth exemplary embodiment of the spring contact pin,

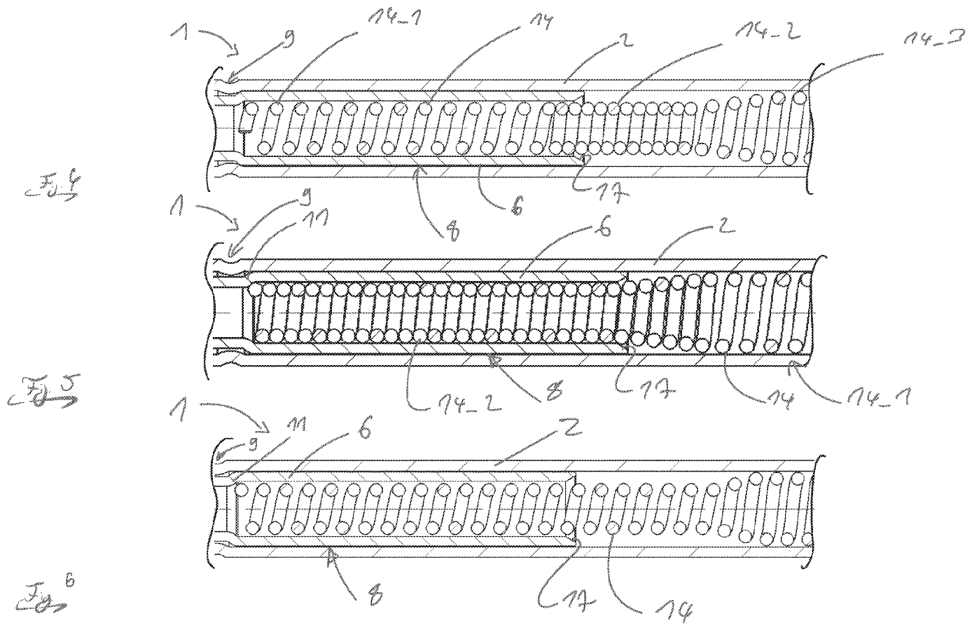

FIG. 6 shows a sixth exemplary embodiment of the spring contact pin,

FIG. 7 shows a seventh exemplary embodiment of the spring contact pin,

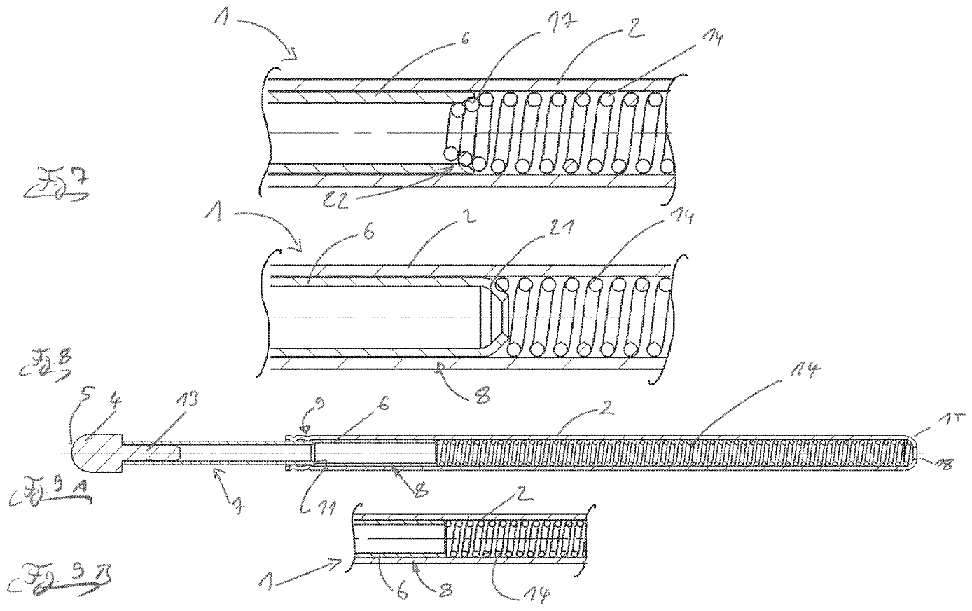

FIG. 8 shows an eighth exemplary embodiment of the spring contact pin and

FIG. 9A and B show a ninth exemplary embodiment of the spring contact pin, in each case in a simplified longitudinal sectional illustration.

In a simplified longitudinal sectional illustration, FIG. 1A shows an advantageous spring contact pin 1, which has a sleeve-shaped housing 2, also referred to as jacket, as well as a contact element 3, which is mounted in the housing 2 in a longitudinally displaceable manner. The contact element 3 has a contact head 4 with a front-side, closed contact surface 5, which is formed for contacting a contact partner in an electrically conductive manner by means of direct contacting. For this purpose, the contact head 4 is manufactured as solid element or solid body (thus without hollow spaces), so that the contact surface 5 is also formed in a closed manner. According to the present exemplary embodiment, the contact surface 5 is formed in a ball-shaped manner. The contact surface 5 can generally also have other shapes, for example, concave, pointed, conical, start-shaped or fork-shaped.

The contact element 3 furthermore has a plunger 6, which is firmly connected to the contact head 4. The plunger 6 is formed as hollow plunger and in a tubular manner for this purpose. The plunger 6 is thus also sleeve-shaped and has an only thin jacket wall, wherein the jacket wall of the plunger 6 is preferably thinner than the jacket wall of the sleeve-shaped housing 2. As shown in FIG. 1A, the plunger 6 reaches far into the housing 2, so that it extends at least over half of the longitudinal extension of the housing and preferably beyond that. The plunger 6 thereby has a section 7 facing the contact head 4 and a section 8 assigned to the housing, wherein the section 8 lies completely within the housing 2, and the section 7 protrudes from the housing at least in the non-actuated state.

FIG. 1B shows an enlarged illustration of the spring contact pin 1 in the region of the spring contact pin 1, in which the plunger 6 penetrates into the housing 2. On its end facing the contact head 4, the housing 2 is formed in an open manner and has a cross sectional tapering 9. In the present case, this cross sectional tapering 9 is realized by means of a flanging 10 of the housing 2.

In its longitudinal extension, the plunger 6 likewise has a cross sectional tapering 11, so that the section 7 has a smaller outer diameter than the section 8 of the plunger 6. Due to the cross sectional tapering 11 and the different outer diameters of the plunger 6 associated therewith, a step is created in the plunger 6, which forms an axial stop 12. The outer diameter of the section 8 is thereby larger than the inner diameter of the cross sectional tapering 9 of the housing 2, so that the axial stop 12 interacts with the cross sectional tapering 9 in a positive manner in the direction of the contact head 4, so that the plunger 6 is prevented from being pushed out of the housing 2 in the direction of the contact head 4.

According to the present exemplary embodiment, as shown in FIG. 1A, the contact head 4 is formed as separate element for the contact plunger 6. For this purpose, the contact head 4 has a plug-in section 13, which is inserted into the section 7 of the plunger 6. The plug-in section 13 is in particular axially pressed into the plunger 6, so that the contact head 4 is held on the plunger 6 by means of interference fit. Optionally, the contact head 4 is additionally welded, soldered to the plunger 6 or is connected to it in a positive manner, for example by means of a flanging or deformation. Due to the two-piece formation of the plunger with the separate contact head 4 and the plunger 6, a simple adaptation of the spring contact pin to different boundary conditions and/or contact partners is ensured. Contact heads 4 with different, in particular differently shaped, contact surfaces 5 can thus be provided and can be connected to the plunger 6, if necessary. In a system of spring contact pins or contact elements, which has a plurality of plungers 6 and contact heads 4, in particular the plungers 6 are formed identically and a plurality of different contact heads 4 are provided, so that the desired spring contact pin can be produced with little effort by means of a combination of a certain contact head 4 with one of the plungers 6.

The spring contact pin 1 furthermore has a spring element 14 in the form of a coil spring. The coil spring 14 is pretensioned between the housing 2 and the contact element 3 in such a way that it pushes the contact element 3 with the contact head 4 out of the housing 2 or pushes the axial stop 12 against the cross sectional tapering 11 of the housing 2, respectively. For this purpose, the spring element 14 supports itself with one end on a housing end 15 of the housing 2 facing away from the contact head 4. With its other end, the spring element 14 supports itself on the contact element 3, in particular on the plunger 6. For this purpose, it is provided according to the present exemplary embodiment that the outer diameter of the spring element 14 is smaller than the inner diameter of the contact plunger 6, so that the spring element 14 extends into the plunger 6. The cross sectional tapering 11 in particular forms an axial stop 16 for the spring element 14, so that the spring element 14 axially supports itself on the cross sectional tapering 11 on the inner side of the plunger 6. In the non-actuated or rebounded state, respectively, as shown in FIG. 1B, the spring element 14 thus extends virtually over the entire length of the housing 2 and over the entire length of the section 8 of the plunger 6.

FIG. 1C shows an enlarged detail view of the spring contact pin 1 in the region of the housing end 15. The spring element 14 preferably has two longitudinal sections, which differ from one another. According to the present exemplary embodiment, the longitudinal section 14_1, which is located within the plunger 6 in the non-actuated state, is formed in a resilient or elastically deformable manner, respectively. The longitudinal section 14_2 located outside the plunger 6, in contrast, is formed in a stiff manner, so that it cannot compressingly engage. This is shown in an exemplary manner in FIG. 1A and C by means of the coils of the coil spring, which abut one another, in the longitudinal section 14_2, while the coils lie axially spaced apart from one another in the longitudinal section 14_1 and thus allow for an axial compressing engagement.

Due to the fact that the longitudinal section 14_2 of the spring element 14, which is exposed from the plunger 6, is formed in a stiff manner, no movement is created between the longitudinal section 14_2 and the inner side of the housing 2 in response to the compressing engagement of the contact element 3 during a test procedure and thus no friction and no wear. The compressing engagement takes place solely within the plunger 6. This has the advantage that the wear of the spring contact pin 1 is reduced as a whole on the one hand and that the wear is prevented by means of the spring element 14 in the region of the electrically conductive contact points between plunger 6 and housing 2. Only plunger 6 and housing 2 rub against one another during operation, whereby the wear is reduced as a whole and the service life of the spring contact pin 1 is increased as a whole therewith. Due to the fact that the spring element 14 extends into the plunger 6 and axially supports itself there, a particularly long guide surface between plunger 6 and housing 2 is ensured, which ensures a precise guidance of the contact element 3 with low friction. A secure electrical connection between the housing 2 and the contact element 3 is additionally ensured by means of the long contact surface.

FIG. 1D shows the spring contact pin 1 in the compressingly engaged state, thus when the contact element 3 is compressingly engage into the housing 2 against the force of the spring element 14. The spring deflection is thereby limited either by means of the spring element 14 itself or by means of the length of the plunger 6, which abuts the housing end 15 of the housing 2. Due to the stiff formation of the longitudinal section 14_2, the latter likewise extends partially into the plunger 6 or to a large extent, depending on how long the plunger 6 is formed to be and how far the displacement path is made possible, so that the longitudinal section 14_1 is located completely within the plunger and is compressed there, as shown in FIG. 1B.

FIG. 1E shows an enlarged illustration of the spring contact pin 1 in the region of the housing end 15 in the compressingly engaged state. On the free end of the section 8, the plunger 6 has a lead-in chamfer 17 for the spring element 14. In response to the compressing engagement, the spring element 14 is thus advantageously guided into the plunger 6, so that the plunger 6 is securely prevented from catching or from seizing on the spring element 14 or the other way around.

It follows from the advantageous formation of the spring contact pin 1 that significantly narrower guide gaps are made possible by means of the combination of two deep-drawn parts (plunger 6 and housing 2), which act as sliding guide when inserted into each other, because the practically realizable diameter tolerances compared to turned parts are better by a factor of approx. 3. The effective contact surfaces between plunger 6 and housing 2 thus increase significantly, whereby a surface pressure and thus directly the frictional wear are reduced. The material usage as a whole decreases many times over, wherein in particular the weight, which is to be moved, of the contact element 3 is reduced and the material costs are reduced. Due to the fact that the contact head 4 and the plunger 6 are formed as separate elements, in particular the advantages additionally result that the coating thicknesses of the two parts, as well as the coating materials and coating technologies, can be specified independently of one another. The base materials can also be chosen and used independently of one another. Unconventional production technologies, in particular for the contact head 4 and, associated therewith, the realization of novel head shapes can also be made possible thereby.

The wear, which still remains and which is caused by the spring element 14 within the plunger 6, is less disruptive there because it does not impact the electrical function of the spring contact pin 1, in particular the contact surfaces. Even though wear still remains, it is separated from the important functional zones or contact zones, respectively, between housing 2 and plunger 6. It is also attained due to the advantageous formation that wear, which may occur in the case of conventional spring contact pins, in the case of which the spring element is pretensioned against the free end of the plunger, is avoided. In the case of a conventional design, abrasion is additionally also created in the functionally important guide region of plunger 6 and housing 2 and remains there. Due to the fact that the wear is now moved into the plunger 6, by means of the spring element 14 protruding into the plunger 6, abrasion also remains essentially within the plunger 6 and does not reach the contact points between plunger 6 and housing 2 or does not reach them as quickly, whereby the service life of the spring contact pin 1 is further increased. The stiff longitudinal section 14_2 of the spring element 14 furthermore has the effect that fewer transverse forces act on the plunger 6, whereby the service life of the spring contact pin is further increased by means of the reduction of frictional forces.

The plunger 6 and the housing 2 advantageously have an advantageous coating for increasing the electrical conductivity and/or for reducing wear. The coating can, for example, be a galvanic noble metallization or the like thereby.

FIG. 2 shows a second exemplary embodiment of the spring contact pin 1, which differs from the first exemplary embodiment in that the spring element 14 does not have a constant diameter, as in the preceding exemplary embodiment. Instead, the diameter of the spring element 14 or the coil spring, respectively, widens towards the housing end 15, so that the spring element 14, on its end facing the housing end 15, is formed to be wider, as shown in FIG. 2. A secure abutment of the spring element 14 against the housing end 15 is ensured thereby, even if said housing end has a remaining opening 18, as shown in the present exemplary embodiment, which is in particular production-related. The housing 2 as well as the plunger 6 are advantageously formed as deep-drawn part. In particular the different cross sections or diameters of the plunger 6, respectively, in the sections 7 and 8 can thus be realized in an advantageous manner. The housing 2 can thus also be produced in a cost-efficient and precise manner. According to the first two exemplary embodiments, the housing end 15 is already shaped in such a way by means of the deep-drawing process that it forms the axial stop for the spring element 14. The flanging 10 is produced subsequently, in order to form the cross sectional tapering 9 on the opposite end.

According to an alternative exemplary embodiment, as shown in FIGS. 3A and 4B, the cross sectional tapering 9 is produced in the form of a step in the deep-drawing process. After the deep-drawing process, the housing end 15 is formed in an open manner or without tapering, respectively, as shown in FIG. 3A. The contact element 3 is thus now axially inserted with the section 7 first, from the side of the housing end 15, as shown by means of an arrow 19 in FIG. 3A. The spring element 14 is subsequently or simultaneously inserted or pushed into the housing 2, respectively, from the housing end 15. The housing end 15 is plastically deformed only subsequently, so that the cross section of the housing 2 is tapered or reduced, respectively, on the housing end 15, as shown in FIG. 3B. For this purpose, the end is bent inwards, as suggested by means of arrows 20 in FIG. 3A and B. The plunger 6 is subsequently held with the spring element 14 in the housing 2 in a captive positive manner. For the final assembly, the contact head 4 is subsequently also assembled to the plunger 6. If the contact head 4 has an outer diameter, which is only as large as the outer diameter of the plunger 6 in the section 7, the contact head 4 can also already be assembled on the plunger 6 prior to the assembly of the plunger 6 in the housing 2 and can be pushed through the housing 2 together with the plunger 6.

FIG. 4 shows a further, fourth exemplary embodiment of the spring contact pin 1 in an enlarged longitudinal sectional illustration. This exemplary embodiment differs from the preceding exemplary embodiments in that the stiff longitudinal section 14_2 is not assigned to the end of the spring element 14 but is formed between two resilient longitudinal sections 14_1 and 14_2, viewed in the longitudinal extension of the spring element 14. In the non-actuated state of the spring contact pin 1, the stiff longitudinal section 14_2 thereby lies in the region, in which the spring element 14 penetrates into the plunger 6. The spring element 14 is thus stiffened in the transition region, so that a canting or tilting of the spring element in response to the compressing engagement of the plunger 6 and thus in response to being pushed onto the spring element 14 is prevented. Due to the fact that the subsequent resilient longitudinal section 14_3, which leads all the way to the housing end 15, can likewise be compressed or elastically deformed, respectively, the spring deflection is increased compared to the preceding exemplary embodiment.

FIG. 5 shows a fifth exemplary embodiment of the spring contact pin 1, which differs from the preceding exemplary embodiments in that in the rebounded state or in the non-actuated state of the spring contact pin 1, respectively, the stiff longitudinal section 14_2 lies completely within the section 8 of the plunger 6. Compared to the exemplary embodiment of FIG. 1, the stiff longitudinal section and the resilient longitudinal section of the spring element 14 are thus interchanged. It is preferably provided thereby that the diameter of the spring element 14 increases in the resilient section, so that the spring element 14 abuts radially against the inner side of the housing 2 in the resilient region, in order to be optimally guided there.

FIG. 6 shows a sixth exemplary embodiment of the spring contact pin 1, which differs from the preceding exemplary embodiments in that the spring element 14 does not have a stiff longitudinal section. However, as shown in the fifth exemplary embodiment, the spring element 14 has a diameter widening into the longitudinal section of the spring element 14, which is radially guided in the housing 2. The widening of the diameter thereby lies axially spaced apart from the plunger 6, so that further regions of the longitudinal section of the spring element 14 can initially penetrate into the plunger 6 with reduced diameter in response to the compressing engagement of the contact element 3.

FIG. 7 shows a further exemplary embodiment of the spring contact pin 1, which differs from the preceding exemplary embodiments in that the spring element 14 supports itself on the end of the plunger 6 facing the housing end 15 and does not penetrate into said plunger. For this purpose, the spring element 14 has, on its end facing the plunger 6, a diameter reduction, so that only the end of the spring element 14 penetrates into the plunger 6 and the plunger 6 is thus centered. The lead-in chamfer 17 of the plunger 6 thereby acts in a centering manner with the coils of the coil spring for the spring element 14 and the plunger 6.

FIG. 8 shows an eighth exemplary embodiment of the spring contact pin 1, which differs from the preceding exemplary embodiments in that the plunger 6 has a diameter reduction, in particular a plastic shaping, similar to that of the housing end 15, from its end facing the housing end 15, wherein the coil spring 14 has a constant diameter. The inner diameter of the tapering of the plunger end is thereby formed to be smaller than the inner diameter of the spring element 14 of the coil spring. With its coils, the coil spring 14 is thus guided between the tapered end 21 and the inner side of the housing 2, whereby a centering is likewise realized. However, the plunger 6 thereby penetrates into the spring element 14 and not the other way around, as in the exemplary embodiment of FIG. 7, for example.

FIG. 9A and B show a ninth exemplary embodiment of the spring contact pin 1, which corresponds to the exemplary embodiments of FIGS. 7 and 8 to the extent that the spring element 14 supports itself on the end of the plunger 6 facing the housing end 15. In contrast to the preceding exemplary embodiments, the spring element 14, however, supports itself directly on the undeformed, flat front wall of the cylindrical section 8 of the plunger 6, as shown in the detail view of FIG. 9B.

1. A spring contact pin (1) for electrically conductively directly contacting a contact partner, with a sleeve-shaped housing (2) and with a contact element (3), which is supported in the housing (2) in a longitudinally displaceable manner and which has a plunger (6), which lies at least partially in the housing (2), and a contact head (4), which lies outside the housing (2) with a contact surface (5) for directly contacting the contact partner, wherein a spring element (14), in particular coil spring, is arranged in the housing (2) in such a way that the contact element (3) can compressingly engage into the housing (2), characterized in that the plunger (6) is formed in a tubular manner as hollow plunger and that the contact surface (5) of the contact head (4) is formed in a closed manner.

2. The spring contact pin according to claim 1, characterized in that the contact head (4) is formed as solid body and has a plug-in section (13), which is axially inserted into the plunger (6).

3. The spring contact pin according to claim 1, characterized in that the plunger (6) is formed as a deep-drawn part.

4. The spring contact pin according to claim 2, characterized in that the plug-in section (13) for electrical and mechanical connection to the plunger (6) is held in the plunger (6) in a non-positive manner, in a positive manner and/or by means of a substance-to-substance bond.

5. The spring contact pin according to claim 2, characterized in that the plug-in section (13) is held in the plunger (6) by means of pressing, flanging, crimping, welding and/or soldering.

6. The spring contact pin according to claim 1, characterized in that the plunger (6) has a cross sectional tapering (11) between its ends and that the spring element (14) extends into the plunger (6) and supports itself axially on the cross sectional tapering (11) on the one hand and on a housing end (15) of the on the other hand.

7. The spring contact pin according to claim 6, characterized in that viewed in the axial extension of the plunger (6), the cross sectional tapering (11) of the plunger (6) is arranged closer to the contact head (4) than to the end of the plunger (6) facing the housing end (15).

8. The spring contact pin according to claim 7, characterized in that the spring element (14) has at least one stiff spring element section (14_2).

9. The spring contact pin according to claim 8, characterized in that the stiff spring element section (14_2) lies at least essentially between the plunger (6) and the housing end (15).

10. The spring contact pin according to claim 7, characterized in that the stiff spring element section (14_2) has an outer diameter, which is smaller than the inner diameter of the housing (2).

11. The spring contact pin according to claim 6, characterized in that on its end facing the housing end (15), the plunger (6) has a lead-in chamfer (17) for the spring element (14).

12. The spring contact pin according to claim 1, characterized in that the housing end (15) is plastically deformed, in particular bent over, for formation of an axial stop for the spring element (14).

13. The spring contact pin according to claim 1, characterized in that the housing (2) has, on its end facing away from the housing end (15), a cross sectional tapering (9), which forms a step, wherein the step is formed as axial stop (12) for the plunger (6), which acts against the force of the spring element (14).

14. The spring contact pin according to claim 1, characterized in that the cross sectional tapering (9) of the housing (2) is produced by means of a flanging or by means of a deep-drawing process.

15. The spring contact pin according to claim 1, characterized in that the length of the section of the plunger (6), which lies at least in the housing (2), corresponds to the length of the housing (2) minus a maximally permissible spring deflection of the spring element (14) and minus a specifiable tolerance value.

16. The spring contact pin according to claim 1, characterized in that the end of the spring element (14) facing the housing end (15) is widened.

17. The spring contact pin according to claim 1, characterized in that outside the plunger (6), the spring element (14) has a longitudinal section, along which the outer diameter of the spring element (14) widens in the direction of the housing end (15), so that the spring element (14) abuts on an inner side of the housing (2) outside the plunger (6).

18. The spring contact pin according to claim 17, characterized in that the longitudinal section forms the stiff longitudinal section (14_2) of the spring element (14).

19. The spring contact pin according to claim 1, characterized in that the plunger (6) has, on its end facing the housing (2), a cross sectional tapering (21), on which the spring element (14) supports itself.

20. The spring contact pin according to claim 19, characterized in that the cross sectional tapering (21) forms a centering chamfer for centering the spring element (14) between the plunger (6) and the housing (2).

21. The spring contact pin according to claim 1, characterized in that the spring element (14) has, on its end facing the plunger (6), a diameter reduction (22) for centering the spring element (14) on the plunger (6).
